(19) United States
(12) Patent Application Publication
(10) Pub. No.: US 2025/0323122 A1
(43) Pub. Date: Oct. 16, 2025

(54) PACKAGE STRUCTURE WITH HEAT DISSIPATION STRUCTURE HAVING ONE OR MORE VAPOR CHAMBERS OVER IC CHIPS

(71) Applicant: Taiwan Semiconductor Manufacturing Company, Ltd., Hsinchu (TW)

(72) Inventors: Shih-Wei Liu, Chiayi City (TW); Sing-Da Jiang, Taichung City (TW); Tsunyen Wu, Hsinchu County (TW); Kathy Wei Yan, Hsinchu (TW)

(21) Appl. No.: 19/250,148

(22) Filed: Jun. 26, 2025

Related U.S. Application Data
(63) Continuation of application No. 18/757,663, filed on Jun. 28, 2024.
(60) Provisional application No. 63/621,558, filed on Jan. 16, 2024.

(51) Int. Cl. H01L 23/427; H01L 21/54; H01L 23/00; H01L 23/31; H01L 23/373; H01L 23/538; H01L 25/065

(52) U.S. Cl. CPC H01L 23/427; H01L 21/54; H01L 23/3736; H01L 23/5383; H01L 24/32; H01L 23/31; H01L 24/08; H01L 24/16; H01L 25/0655; H01L 2224/08235; H01L 2224/16225; H01L 2224/32225

(57) ABSTRACT

Various embodiments of the present disclosure are directed towards a semiconductor package structure including a support structure having a first surface opposite a second surface. A first integrated circuit (IC) chip is on the first surface of the support structure. A capping structure is on the second surface of the support structure. A vapor chamber is disposed in the support structure and overlies at least a portion of the first IC chip.

### REFERENCE TO RELATED APPLICATIONS

This application is a Continuation of U.S. application Ser. No. 18/757,663, filed on Jun. 28, 2024, which claims the benefit of U.S. Provisional Application No. 63/621,558, filed on Jan. 16, 2024. The contents of the above-referenced patent applications are hereby incorporated by reference in their entirety.

### BACKGROUND

Integrated circuit (IC) chips having semiconductor devices are essential for many modern electronic devices. With the advancement of electronic technology, the semiconductor devices are becoming increasingly smaller in size while having greater functionality and greater amounts of integrated circuitry. Due to the miniaturized scale of the semiconductor device, advanced semiconductor packaging is widely used to integrated several IC chips into a single multi-chip package. Among other things, the integration of multiple IC chips in the semiconductor package provides a higher density of semiconductor devices with smaller form factors, thereby allowing for increased performance and lower power consumption.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a semiconductor package structure including a heat dissipation structure comprising a vapor chamber over a plurality of integrated circuit (IC) chips.

FIG. 2 illustrates a cross-sectional view of some other embodiments of a semiconductor package structure including a heat dissipation structure comprising a plurality of vapor chambers over a plurality of IC chips.

FIGS. 3A-3C illustrate layout views of various embodiments of the semiconductor package structure of FIG. 2 taken along the line A-A′ of FIG. 2.

FIGS. 4A-4E illustrate cross-sectional views of some other embodiments of the semiconductor package structure of FIG. 2.

FIG. 4F illustrates a top view of some embodiments of a portion of a thermal dispersion enhancement structure disposed in a vapor chamber of the semiconductor package structure of FIG. 4A taken along the line B-B′ of FIG. 4A.

FIGS. 4G and 4H illustrate various cross-sectional views of some embodiments of a thermal dispersion enhancement structure disposed in a vapor chamber.

FIG. 5A illustrates a cross-sectional view of some embodiments of a semiconductor package structure including a vapor chamber that continuously laterally extends from over a first IC chip to over a second IC chip.

FIG. 5B illustrates a cross-sectional view of some other embodiments of the semiconductor package structure of FIG. 2, where one or more vapor channels extend between adjacent vapor chambers.

FIG. 6 illustrates a layout view of some embodiments of the semiconductor package structure of FIG. 5B taken along the line A-A′ of FIG. 5B.

FIGS. 7A and 7B illustrate cross-sectional views of some other embodiments of the semiconductor package structure of FIG. 2.

FIGS. 8-17 illustrate cross-sectional views of some embodiments of a method of forming a semiconductor package structure having a heat dissipation structure that includes one or more vapor chambers over a plurality of IC chips.

FIG. 18 illustrates a flow diagram of some embodiments of a method of forming a semiconductor package structure comprising a heat dissipation structure includes one or more vapor chambers over a plurality of IC chips.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package structure may include a plurality of integrated circuit (IC) chips on a base structure. The IC chips each comprise a plurality of semiconductor devices (e.g., transistors). The base structure may be or comprise an interposer that electrically couples the IC chips together and/or to other electronic devices through conductive interconnects such as wires, vias, bond structures and through substrate vias (TSVs). The semiconductor package structure further includes a support structure over the plurality of IC chips that reduces mechanical stress on the IC chips and/or the base structure. During operation of the semiconductor package structure, the semiconductor devices and/or the conductive interconnects may generate heat (e.g., due to Joule heating). Dissipation of heat in ICs has become increasingly important as devices are scaled down and are more densely packed together.

The semiconductor package structure may have localized high temperature regions across the IC chips and/or base structure. For example, regions of the IC chips and/or the base structure operating at relatively high power may generate high heat that leads to localized high temperature regions in the semiconductor package structure. The support structure may, for example, be or comprise a silicon substrate that is a poor conductor of heat and directly overlies these localized high temperature regions. The poor heat conductance of the support structure mitigates dissipation of heat at these localized high temperature regions which can lead to reduced reliability and/or poor circuit performance. For instance, the localized high temperature regions can cause burn out failure in the semiconductor devices and/or delamination in layers of or around the conductive interconnects. In addition, the localized high temperature regions may cause large temperature variations across the semiconductor package structure that can result in timing uncertainty. This may significantly reduce the performance of the semiconductor devices in high-performance computing applications (e.g., advanced server and networking applications) that call for high data rates and reduced latency.

Various embodiments of the present disclosure are directed towards a semiconductor package structure having a heat dissipation structure on a plurality of IC chips and configured to enhance thermal diffusion. In some embodiments, the semiconductor package structure includes the plurality of IC chips on a base structure and a heat dissipation structure on the plurality of IC chips. The IC chips each comprise a plurality of semiconductor devices. The heat dissipation structure includes a support structure, a capping structure on the support structure, and one or more vapor chambers embedded in the capping structure. The one or more vapor chambers are configured to enhance thermal dissipation in the vertical direction away from the plurality of semiconductor devices of the IC chips and towards the capping structure. The capping structure has a relatively high thermal conductivity (e.g., greater than that of the support structure) and is configured to efficiently spread heat away from the IC chips to the external environment. The one or more vapor chambers enhancing thermal dissipation in the vertical direction and the high thermal conductivity of the capping structure increases a heat dissipation performance of the semiconductor package structure and facilitates heat being transferred away from potential localized high temperature regions. As a result, issues (e.g., timing uncertainty, burn out failure, etc.) due to high heat and/or large temperature variations across the IC chips are reduced, thereby increasing a performance and reliability of the semiconductor package structure.

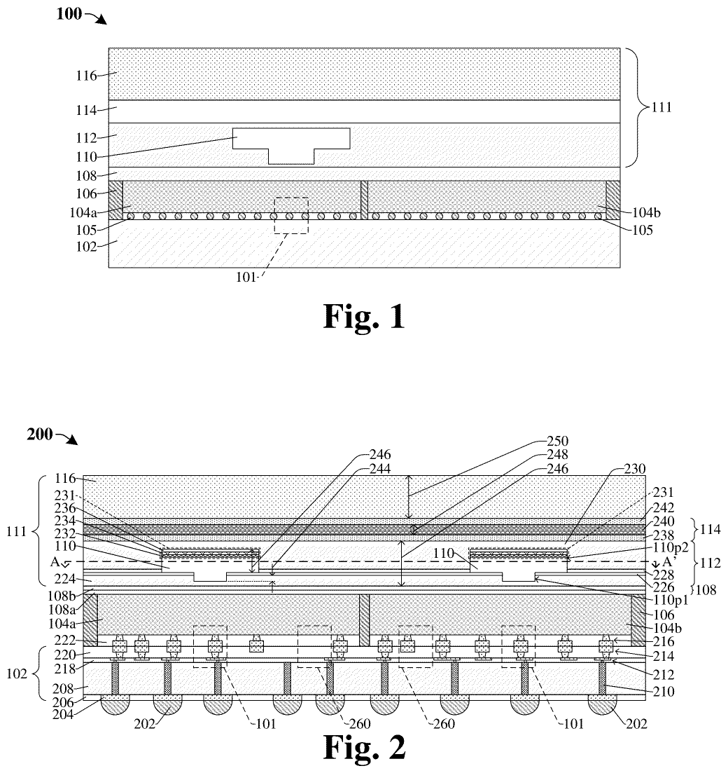

FIG. 1 illustrates a cross-sectional view 100 of some embodiments of a semiconductor package structure including a heat dissipation structure 111 comprising a vapor chamber 110 over a plurality of integrated circuit (IC) chips 104a-b.

The semiconductor package structure includes a base structure 102, the plurality of IC chips 104a-b, and the heat dissipation structure 111. In various embodiments, the plurality of IC chips 104a-b respectively comprise a plurality of semiconductor devices disposed on a semiconductor substrate and an interconnect structure electrically coupled to the plurality of semiconductor devices (not shown). The semiconductor devices may be or comprise one or more electronic device such as diodes, transistors, capacitors, resistors, or the like. Further, the IC chips 104a-b may be or comprise one or more IC dies or a stack of IC dies. In various embodiments, the IC chips 104a-b may each be a system-on-chip (SoC), a system-on-integrated-circuit (SoIC), or the like. In some embodiments, the base structure 102 is configured as an interposer and comprises conductive interconnect routing, through substrate vias (TSVs), contact pads, or the like (not shown) configured to electrically couple the IC chips 104a-b to one another and/or to another electronic device (not shown). The IC chips 104a-b are bonded to the base structure 102 by way of a plurality of conductive bonding elements 105. The conductive bonding elements 105 facilitate electrical coupling between the IC chips 104a-b and the base structure 102. A filler layer 106 overlies the base structure 102 and is disposed around and between each of the IC chips 104a-b. An upper bond structure 108 is disposed between the heat dissipation structure 111 and the plurality of IC chips 104a-b.

The heat dissipation structure 111 overlies the plurality of IC chips 104a-b and is configured to enhance thermal dissipation in the semiconductor package structure. The heat dissipation structure 111 includes a support structure 112, a thermal interface structure 114, a capping structure 116, and one or more vapor chambers 110. The support structure 112 overlies the plurality of IC chips 104a-b. In various embodiments, the support structure 112 comprises one or more substrates (e.g., silicon substrates), one or more dielectric layers (e.g., comprising silicon dioxide or some other suitable dielectric), or the like (not shown). The vapor chamber 110 is embedded or disposed in the support structure 112. In some embodiments, the vapor chamber 110 is defined by at least one or more surfaces of the support structure 112 and directly overlies at least a first region 101 of a first IC chip 104a. In various embodiments, the first region 101 of the first semiconductor die 104a comprises semiconductor devices (not shown) that operate at high power and/or are densely packed together such that the first region 101 has the potential to be a localized high temperature region during operation of the semiconductor package structure.

The thermal interface structure 114 is disposed between the support structure 112 and the capping structure 116. In some embodiments, the thermal interface structure 114 is configured to facilitate bonding the capping structure 116 to the support structure 112 and/or provide a thermal interface between the support structure 112 and the capping structure 116. The capping structure 116 has a relatively high thermal conductivity and is configured to efficiently spread heat away from the plurality of IC chips 104a-b to the external environment. For example, the thermal conductivity of the capping structure 116 is greater than that of the one or more substrates and/or dielectric layers of the support structure 112.

The vapor chamber 110 is configured to enhance thermal dissipation in a vertical direction from the plurality of IC chips 104a-b towards the capping structure 116. In some embodiments, the vapor chamber 110 is sealed with and/or comprises a vaporizable working fluid that may undergo an evaporation process to be converted to a vapor and the vapor may a undergo a condensation process to be converted back into a liquid. In various embodiments, the vaporizable working fluid may, for example, be or comprise a chlorofluorocarbon, a hydrochlorofluorocarbon, water, alcohol, silicon oil, liquid nitrogen, fluorine-containing fluid, acetone, methanol, ethanol, heptane, ammonia, some other suitable cooling liquid, or any combination of the foregoing. The vaporizable working fluid is disposed in the vapor chamber 110 and is configured to facilitate transferring heat in the vertical direction from the IC chips 104a-b towards the capping structure 116. For instance, during operation of the semiconductor package structure heat generated from the IC chips 104a-b and/or the base structure 102 causes the vaporizable working fluid to evaporate and be converted into a vapor. This evaporation efficiently moves heat in the vertical direction towards the capping structure 116. When the heat is transferred to the capping structure 116, the relatively high thermal conductivity of the capping structure 116 facilities spreading the heat to the external environment and away from the IC chips 104a-b. By efficiently dissipating heat away from the IC chips 104a-b by the vapor chamber 110 and the capping structure 116, issues (e.g., timing uncertainty, burn out failure, etc.) due to high heat across the IC chips 104a-b is reduced, thereby increasing a performance and reliability of the semiconductor package structure.

Further, in some embodiments, the vapor chamber 110 is advantageously disposed directly over the first region 101 of the first semiconductor die 104a. As discussed above, the first region 101 has the potential to be a localized high temperature region. Disposing the vapor chamber 110 directly over the first region 101 facilitates efficiently dissipating heat away from the first region 101, thereby mitigating the formation of a localized high temperature at and/or around the high-power semiconductor devices and/or the densely packed semiconductor devices in the first region 101. As a result, an overall performance and reliability of the semiconductor package structure is increased.

FIG. 2 illustrates a cross-sectional view 200 of some other embodiments of a semiconductor package structure including a heat dissipation structure 111 comprising a plurality of vapor chambers 110 over a plurality of IC chips 104a-b.

The semiconductor package structure includes the plurality of IC chips 104a-b, a base structure 102, and the heat dissipation structure 111. In some embodiments, the semiconductor package structure is a chip on wafer on substrate (COWOS) package structure, a SoIC package structure, a three-dimensional IC (3D IC) package structure, or some other suitable package structure.

In some embodiments, the base structure 102 is configured as an interposer comprising a lower substrate 208, a plurality of TSVs 210, a plurality of conductive interconnect structures 212, and a first plurality of conductive bond structures 214. The lower substrate 208 may, for example, be or comprise silicon, germanium, silicon germanium, some other suitable substrate material, or any combination of the foregoing. A lower dielectric layer 206 is disposed along a lower surface of the lower substrate 208 and a plurality of lower bond pads 204 are disposed in the lower dielectric layer 206. The lower bond pads 204 are aligned with and electrically coupled to at least one TSV in the plurality of TSVs 210. A plurality of solder bumps 202 are disposed on the lower bond pads 204 and are configured to electrically couple and bond the base structure 102 to another device (e.g., a printed circuit board (PCB) or some other suitable device). The plurality of conductive interconnect structures 212 are disposed in a dielectric structure 218 on an upper surface of the lower substrate 208. In some embodiments, the plurality of conductive interconnect structures 212 include conductive contacts, conductive vias, and/or conductive wires. The first plurality of conductive bond structures 214 are disposed in a first dielectric structure 220. The first plurality of conductive bond structures 214 include bond vias, bond pads, other suitable bond structures, or any combination of the foregoing. Conductive features of the base structure 102 are configured to electrically couple the plurality of IC chips 104a-b to one another and/or to another device (e.g., a PCB).

The plurality of IC chips 104a-b overlie the base structure 102. The IC chips 104a-b comprise a second plurality of conductive bond structures 216 disposed in a second dielectric structure 222. The second plurality of conductive bond structures 216 include bond vias, bond pads, other suitable bond structures, or any combination of the foregoing. One or more bonding interfaces are disposed between the base structure 102 and the IC chips 104a-b. The first plurality of conductive bond structures 214 meet the second plurality of conductive bond structures 216 at the one or more bonding interfaces. In various embodiments, the one or more bonding interfaces include conductor-to-conductor bonds and dielectric-to-dielectric bonds.

The IC chips 104a-b may each be a SoC, a SoIC, a semiconductor die, or the like. In various embodiments, the IC chips 104a-b are configured as a SoC having a chiplet design that each comprise one or more chiplets. For example, the IC chips 104a-b may each be or comprise one or more of a switch chip, a memory chip, an application-specific integrated circuit (ASIC), a central processing unit (CPU), a graphics processing unit (GPU), a data processing unit (DPU), or some other suitable device. The IC chips 104a-b each comprise one or more of a digital circuit, an analog circuit, a mixed-signal circuit, and so on. In some embodiments, circuits of the IC chips 104a-b include a plurality of semiconductor devices (not shown) that may be or comprise transistors, memory devices, resistors, diodes, capacitors, some other electronic devices, or any combination of the foregoing. For example, the circuits of the IC chips 104a-b include complementary metal-oxide semiconductor (CMOS) transistors, planar CMOS transistors, fin field-effect transistors (FinFETs), gate-all-around (GAA) transistors, nanosheet transistors, some other electronic device, or any combination of the foregoing.

In some embodiments, the IC chips 104a-b respectively comprises one or more semiconductor substrate portions and one or more interconnect structures. The semiconductor portion may, for example, be or comprise silicon, germanium, silicon germanium, epitaxial silicon, a silicon-on-insulator (SOI) substrate, some other suitable substrate material, or any combination of the foregoing. The plurality of semiconductor devices are formed in and/or on the one or more semiconductor portions. The one or more interconnect structures is/are disposed on a corresponding one of the one or more semiconductor portions. Each interconnect structure is disposed on the corresponding semiconductor portion and is configured to provide electrical connections to the plurality of semiconductor devices. In various embodiments, the interconnect structure comprises a plurality of conductive interconnect features that are surrounded by or disposed in one or more dielectric layers. The conductive interconnect features may, for example, include conductive contacts, conductive wires, conductive vias, or the like.

A filler layer 106 overlies the base structure 102 and is disposed around and/or between the IC chips 104a-b. The filler layer 106 may, for example, be or comprise an oxide (e.g., silicon dioxide), a resin, or some other suitable material. An upper bond structure 108 overlies the plurality of IC chips 104a-b. The upper bond structure 108 comprises a first dielectric bond layer 108a on the IC chips 104a-b and a second dielectric bond layer 108b on the heat dissipation structure 111. In various embodiments, the first and second dielectric bond layers 108a, 108b may, for example, be or comprise silicon dioxide or some other suitable dielectric material.

The heat dissipation structure 111 overlies the plurality of IC chips 104a-b and is configured to enhance thermal dissipation in the semiconductor package structure. The heat dissipation structure 111 includes a support structure 112, a thermal interface structure 114, a capping structure 116, and a plurality of vapor chambers 110. The support structure 112 overlies the plurality of IC chips 104a-b and the thermal interface structure 114 is disposed between the support structure 112 and the capping structure 116. In some embodiments, the support structure 112 includes a first substrate 224, a first dielectric layer 226, a second dielectric layer 228, and a second substrate 230. The first substrate 224 and the second substrate 230 may, for example, be or comprise silicon, epitaxial silicon, germanium, silicon germanium, some other suitable substrate material, or the like. The first dielectric layer 226 and the second dielectric layer 228 may, for example, be or comprise silicon dioxide or some other suitable material. In various embodiments, a thickness of the first substrate 224 is less than a thickness of the second substrate 230.

The plurality of vapor chambers 110 are embedded in the support structure 112 and are each defined by at least one or more surfaces of the support structure 112. In some embodiments, the plurality of vapor chambers 110 include a first portion 110p1 and a second portion 110p2. The second portion 110p2 directly overlies and is in fluid connection with the first portion 110p1. In some embodiments, each of the vapor chambers 110 has a bottom surface facing the plurality of IC chips 104a-b and a top surface facing the capping structure 116, where an area of the bottom surface of the vapor chamber 110 is less than an area of the top surface of the vapor chamber 110. In various embodiments, a width or volume of the first portion 110p1 is less than a width or volume of the second portion 110p2. The width or volume of the first portion 110p1 being less than the width or volume of the second portion 110p2 facilitates heat being efficiently directed towards the capping structure 116. For instance, the shape of the vapor chamber 110 facilitates vapor in the vapor chamber being directed from the smaller first portion 110p1 to the larger second portion 110p2, thereby promoting the transfer of heat towards the capping structure 116.

In some embodiments, the thermal interface structure 114 includes a first thermal spreading layer 238, a thermal interface layer 240, and a second thermal spreading layer 242. The first and second thermal spreading layers 238, 242 may, for example, be or comprise a metal, such as copper, aluminum, tungsten, silver, some other metal or an alloy thereof. The thermal interface layer 240 may, for example, be or comprise lead, tin, silver, copper, indium, an alloy (e.g., a solder alloy, an indium solder alloy, etc.) thereof, or some other suitable material. The first and second thermal spreading layers 238, 242 are configured to facilitate spreading heat and/or directing heat from the support structure 112 to the capping structure 116. The thermal interface layer 240 is configured to bond the capping structure 116 to the support structure 112 and provide a thermal interface between the capping structure 116 and the support structure 112.

The capping structure 116 overlies the support structure 112 and is configured to dissipate or spread heat from the semiconductor package structure to the external environment. In some embodiments, the capping structure 116 is configured as or referred to as a heat spreader structure. The capping structure 116 has a relatively high thermal conductivity that facilitates spreading heating and/or dissipating heat to the external environment. The capping structure 116 may, for example, be or comprise a metal, such as copper, aluminum, tungsten, silver, some other metal or alloy thereof, graphite, some other suitable material, or any combination of the foregoing. In various embodiments, a thermal conductivity of the capping structure 116 is greater than that of the first and second substrates 224, 230 and the first and second dielectric layers 226, 228. In some embodiments, the thermal conductivity of the capping structure 116 is, for example, greater than about 100 watts per meter kelvin (W/m*K), within a range of about 200 to 500 W/m*K, about 400 W/m*K, or some other suitable value. In yet further embodiments, thermal conductivities of the first and second thermal spreading layers 238, 242 are greater than that of the first and second substrates 224, 230 and the first and second dielectric layers 226, 228. In various embodiments, when viewed in top view an area of the capping structure 116 is equal to or substantially equal to an area of the base structure 102.

The vapor chambers 110 are configured to enhance thermal dissipation in a vertical direction from the plurality of IC chips 104a-b towards the capping structure 116, thereby increasing an overall thermal dissipation performance of the semiconductor package structure. In some embodiments, the vapor chambers 110 comprise and are sealed with a vaporizable working fluid (e.g., a chlorofluorocarbon, a hydrochlorofluorocarbon, water, alcohol, silicon oil, liquid nitrogen, fluorine-containing fluid, acetone, methanol, ethanol, heptane, ammonia, etc.). In various embodiments, the vaporizable working fluid is disposed in at least the first portion 110p1 of each of the vapor chambers 110. The vaporizable working fluid is configured to facilitate spreading heat in the vertical direction from the first portion 110p1 of the vapor chambers 110 towards the second portion 110p2 of the vapor chambers. For instance, during operation of the semiconductor package structure, current running through structures (e.g., conductive interconnects and/or semiconductor devices) of the IC chips 104a-b and/or the base structure 102 generates heat (e.g., due to Joule heating). The generated heat is directed towards the vaporizable working fluid in the vapor chambers 110 that can induce evaporation of the vaporizable working fluid into a vapor. The evaporation of the vaporizable working fluid into the vapor efficiently transfers the heat in the vertical direction towards the capping structure 116. Further, the vapor may undergo a condensation process in the second portion 110p2 as heat is transferred towards the capping structure 116, where the condensation process cools down the vapor and converts it back into a liquid. Accordingly, the vaporizable working fluid is configured to undergo evaporation processes and condensation processes during operation of the semiconductor package structure that facilitates efficiently dissipating heat away from the plurality of IC chips 104a-b, thereby increasing a performance and reliability of the semiconductor package structure.

A thermal dispersion enhancement structure 231 is disposed in the vapor chambers 110. In some embodiments, the thermal dispersion enhancement structure 231 is disposed on an upper surface of the second substrate 230 that defines a top surface of the vapor chambers 110. In various embodiments, the thermal dispersion enhancement structure 231 includes a dielectric layer 236, a seed layer 234 on the dielectric layer 236, and a thermal dispersion enhancement layer 232 on the seed layer 234. In various embodiments, the thermal dispersion enhancement structure 231 is configured to increase an ability for the vapor chambers 110 to transfer heat towards the capping structure 116. For example, the seed layer 234 and the thermal dispersion enhancement layer 232 have a thermal conductivity greater than that of the first and second substrates 224, 230 and the first and second dielectric layers 226, 228.

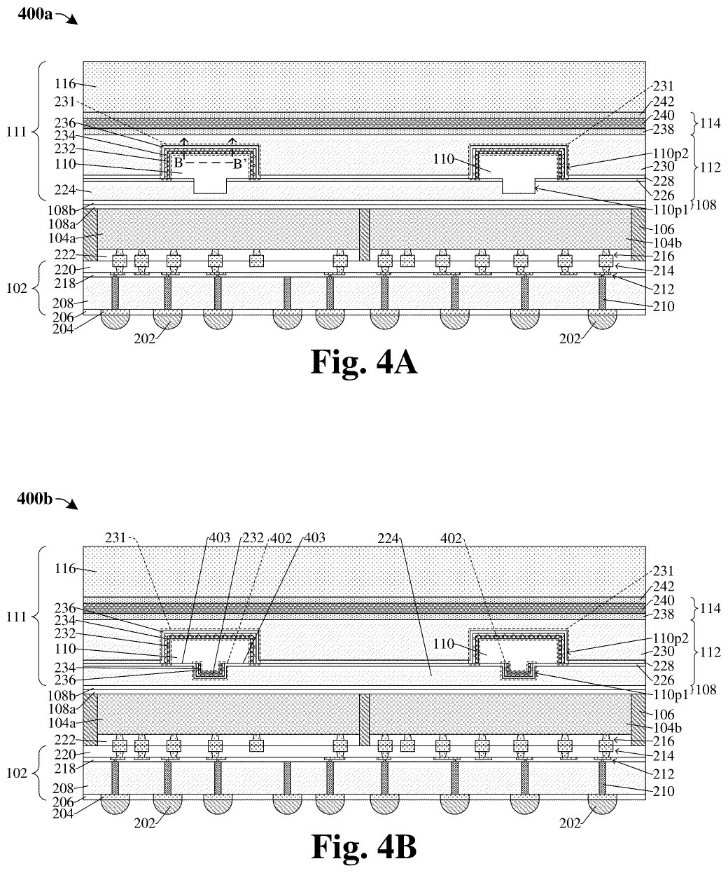

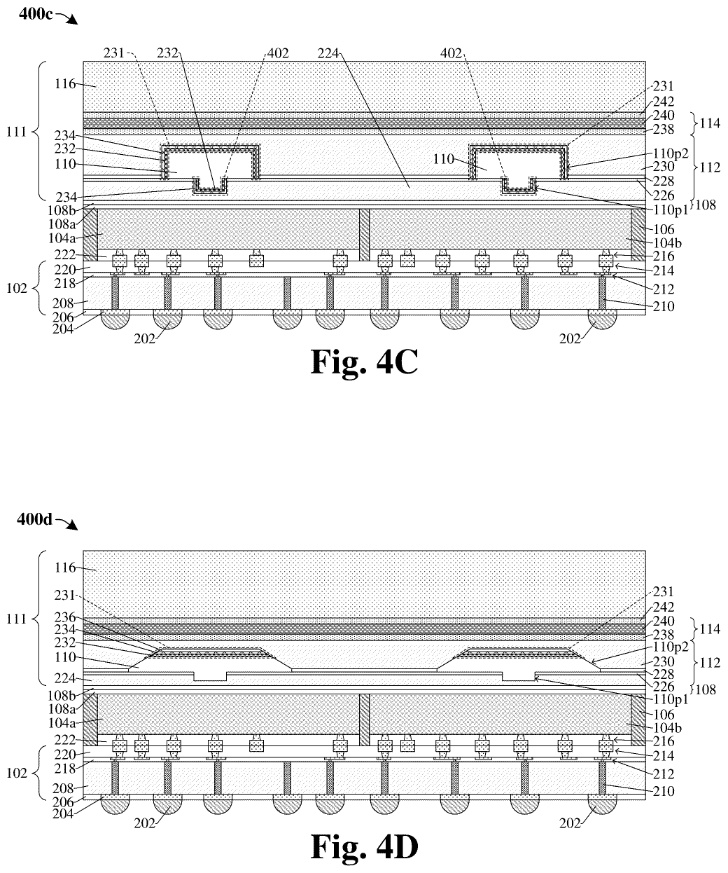

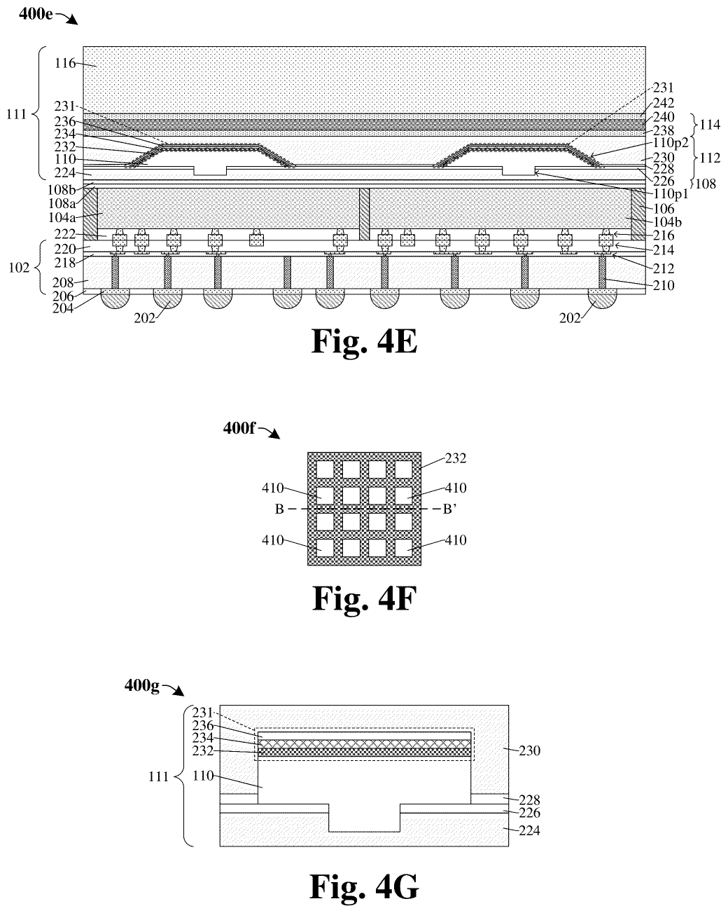

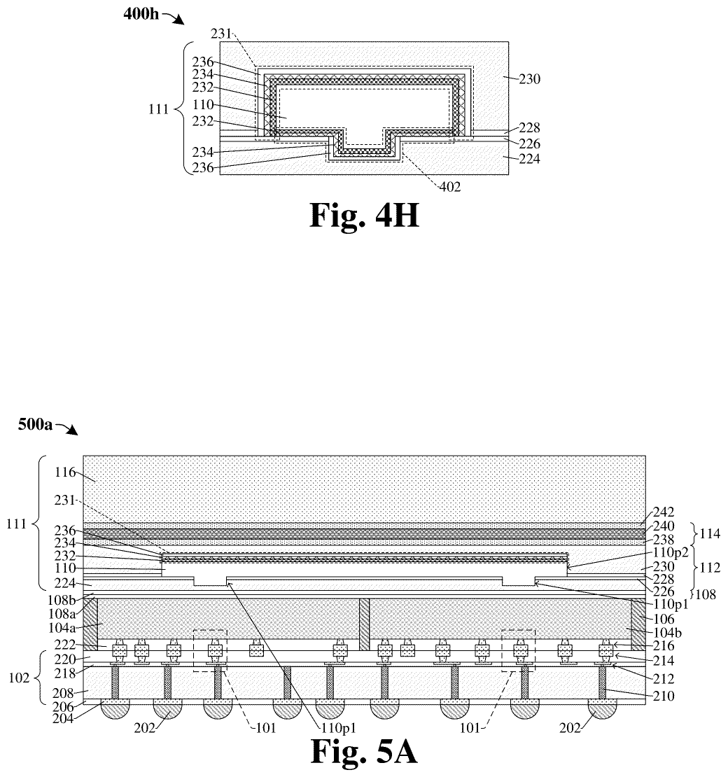

In yet further embodiments, the thermal dispersion enhancement layer 232 comprises a plurality of pores and/or has a grid structure or mesh structure when viewed in top view (e.g., as shown in FIG. 4F). In some embodiments, the thermal dispersion enhancement layer 232 is configured to assist in the evaporation processes and/or condensation processes, thereby improving heat dissipation efficiency of the vapor chambers 110. For example, vapor generated from the vaporizable working fluid may be spread on surfaces of the thermal dispersion enhancement layer 232, where the thermal dispersion enhancement layer 232 improves an ability to cool down the vapor by wicking away condensed liquids on surfaces of the thermal dispersion enhancement layer 232 by capillary action, thereby improving condensation of the vapor. In yet further embodiments, the thermal dispersion enhancement layer 232 may be disposed on one or more surfaces of the support structure 112 defining the first portion 110p1 of the vapor chambers 110 (e.g., as shown in FIG. 4B) such that the mesh structure of the thermal dispersion enhancement layer 232 conveys the vaporizable working fluid by capillary action. As a result, the vaporizable working fluid is spread on surfaces of the thermal dispersion enhancement layer 232, which may improve evaporation of the vaporizable working fluid. Accordingly, the thermal dispersion enhancement structure 231 increases an ability to efficiently dissipate heat away from the IC chips 104a-b.

The dielectric layer 236 may, for example, be or comprise silicon dioxide or some other suitable dielectric material. The seed layer 234 may, for example, be or comprise titanium, tantalum, a nitride (e.g., titanium nitride, tantalum nitride, etc.), copper, or the like. The thermal dispersion enhancement layer 232 may, for example, be or comprise copper, copper powder, or some other suitable material. In some embodiments, the thermal dispersion enhancement layer 232 is configured as and/or referred to as a wicking layer or a wicking structure.

Further, in some embodiments, the vapor chambers 110 are advantageously disposed directly over a corresponding first region 101 of the IC chips 104a-b, where the first portion 110p1 of each vapor chamber 110 directly overlies the corresponding first region 101. In various embodiments, the first region 101 of the IC chips 104a-b is a region that has the potential to be a localized high temperature region. For example, each of the IC chips 104a-b has the first region 101 and an adjacent second region 260, where during operation of the semiconductor package structure the first region 101 generates greater heat than the second region 260. In some embodiments, the first region 101 comprises one or more of a CPU, a GPU, high-voltage devices, a high density of semiconductor devices, a high density of conductive interconnect structures, or the like and the second region 260 comprises one or more of a logic circuit, a memory containing chip or circuit, low voltage devices, a low density of semiconductor devices, or the like. Accordingly, by virtue of the type or function of devices and/or a density of the devices in the first region 101, high temperatures are likely to accumulate in the first region 101. By disposing the vapor chambers 110 directly over the first regions 101 of the IC chips 104a-b, heat may be efficiently dissipated away from the first regions 101, thereby mitigating the formation of a localized high temperature at and/or around the semiconductor devices in the first regions. This, in part, increases an overall performance and reliability of the semiconductor package structure.

In some embodiments, a height 244 of the first portion 110p1 of the vapor chambers 110 is less than a height 246 of the second portion 110p2 of the vapor chambers 110 such that a volume of the second portion 110p2 is greater than a volume of the first portion 110p1. As a result, vapor in the vapor chambers 110 may efficiently be directed towards the capping structure 116, thereby increasing thermal dissipation in the semiconductor package structure.

In some embodiments, a height 246 of the support structure 112 is greater than a height 250 of the capping structure 116. In further embodiments, a ratio of the height 250 of the capping structure 116 and the height 246 of the support structure 112 is within a range of about 0.34 to 1 or some other suitable value. In various embodiments, the ratio of the height 250 and the height 246 being equal to or less than 1 facilitates a volume of the capping structure 116 being sufficiently large enough to efficiently dissipate heat into the external environment while maintaining a structural integrity of the support structure 112. In further embodiments, the ratio of the height 250 and the height 246 being equal to or greater than 0.34 facilitates a volume of the capping structure 116 being sufficiently large enough to efficiently dissipate heat into the external environment. In yet further embodiments, the ratio of the height 250 and the height 246 being equal to or less than 1 increases an ability for the capping structure 116 to dissipate heat while reducing mechanical stress on the support structure 112 and underlying structures (e.g., the plurality of IC chips 104a-b). In various embodiments, the height 246 of the support structure 112 is equal to the height 250 of the capping structure 116. In yet further embodiments, a sum of the height 246 of the support structure 112, a height 248 of the thermal interface layer 240, and the height 250 of the capping structure 116 (e.g., height 246+height 248+height 250) is less than or equal to about 31 millimeters (mm) or some other suitable value. In such embodiments, the sum of the heights 246, 248, 250 being less than or equal to about 31 mm facilitates the heat dissipation structure 111 efficiently dissipating heat from the semiconductor package structure while reducing an overall height of the semiconductor package structure.

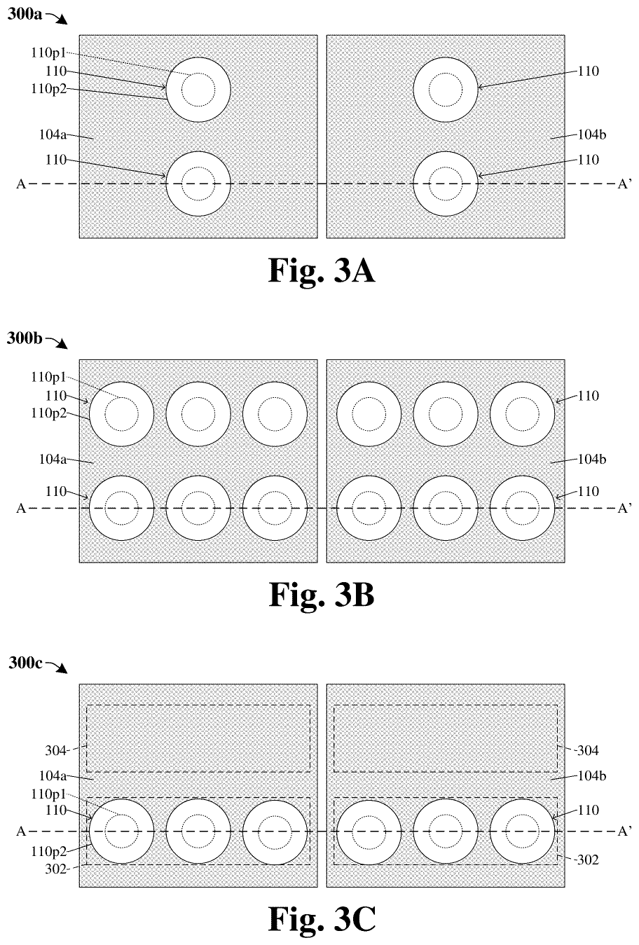

FIGS. 3A-3C illustrate layout views 300a-c of various embodiments of the package structure of FIG. 2 taken along the line A-A′ of FIG. 2. For ease of illustration, the vapor chambers 110 and the IC chips 104a-b of the package structure of FIG. 2 are illustrated in FIGS. 3A-3C while other structures of FIG. 2 are omitted.

As illustrated in the layout view 300a of FIG. 3A, the vapor chambers 110 each have a circular shape. A width of the second portion 110p2 of each vapor chamber 110 is greater than a width of the corresponding first portion 110p1. In various embodiments, the first portion 110p1 and the second portion 110p2 are concentric with one another. In various embodiments, the first portion 110p1 and the second portion 110p2 may each have a circular shape, an oval shape, a rectangular shape, or some other suitable shape when viewed from above.

As illustrated in the layout view 300b of FIG. 3B, the vapor chambers 110 are disposed in an array comprising a plurality of rows and a plurality of columns over each of the IC chips 104a-b. It will be appreciated that while FIG. 3B illustrates an array including two rows and three columns of vapor chambers 110 over each IC chip 104a-b, any number of rows and/or columns over the IC chips 104a-b are amenable.

As illustrated in the layout view 300c of FIG. 3C, the plurality of IC chips 104a-b respectively comprise a first device region 302 and a second device region 304. In some embodiments, the first device region 302 may comprise circuitry and/or semiconductor devices that are prone to generating localized high temperatures in the corresponding IC chip. For example, the first device region 302 may include a CPU, a GPU, high-voltage devices, a high density of semiconductor devices, or the like. Further, the second device region 304 may, for example, include a logic circuit, low-voltage devices, a low density of semiconductor devices, or the like. Accordingly, by virtue of the type or function of devices and/or a density of the devices in the first device region 302, high temperatures are likely to accumulate in the first device region 302 during operation of the semiconductor package. Disposing the vapor chambers 110 over the first device region 302 of the IC chips 104a-b facilitates effectively dissipating heat away from the semiconductor devices of the first device region 302. In further embodiments, the vapor chambers 110 may be laterally offset from the second device region 304 of the IC chips 104a-b, thereby increasing an ability for the support structure (112 of FIG. 2) to provide structural support for the semiconductor package structure.

FIG. 4A illustrates a cross-sectional view 400a of some other embodiments of the semiconductor package structure of FIG. 2, where the thermal dispersion enhancement structure 231 extends along opposing sidewalls and lateral surfaces of the second substrate 230 defining the second portion 110p2 of each of the vapor chambers 110. This increases an ability for the thermal dispersion enhancement structure 231 to assist/enhance transferring heat towards the capping structure 116. For example, by disposing the thermal dispersion enhancement structure 231 along the surfaces of the second substrate 230 defining the second portion 110p2 of the vapor chambers 110 a surface area of the thermal dispersion enhancement layer 232 in the vapor chambers 110 is increased. Accordingly, the thermal dispersion enhancement layer 232 may further assist/enhance the evaporation and/or condensation processes in the vapor chambers 110 during operation of the semiconductor package structure. In various embodiments, the dielectric layer 236, the seed layer 234, and the dielectric layer 236 each have a U-shape when viewed in cross section. In further embodiments, the dielectric layer 236 is part of the second dielectric layer 228.

FIG. 4B illustrates a cross-sectional view 400b of some other embodiments of the semiconductor package structure of FIG. 4A, where a second thermal dispersion enhancement structure 402 is disposed along opposing sidewalls and lateral surfaces of the first substrate 224 defining the first portion 110p1 of each of the vapor chambers 110. In various embodiments, the second thermal dispersion enhancement structure 402 is configured as the thermal dispersion enhancement structure 231 of FIG. 2. In some embodiments, the thermal dispersion enhancement structure 231 and the second thermal dispersion enhancement structure 402 each comprise a dielectric layer 236, a seed layer 234, and a thermal dispersion enhancement layer 232.

Disposing the second thermal dispersion enhancement structure 402 along the surfaces of the first substrate 224 defining the first portions 110p1 of the vapor chambers 110 further increases an ability to transfer heat towards the capping structure 116. For example, the thermal dispersion enhancement layer 232 of the second thermal dispersion enhancement structure 402 assists/enhances evaporating the vaporizable working fluid in the vapor chambers 110 by spreading the vaporizable working fluid by capillary action on surfaces of the thermal dispersion enhancement layer 232. In some embodiments, the relatively high thermal conductivity of the thermal dispersion enhancement layer 232 may facilitate heat from the IC chips 104a-b being directed to the vaporizable working fluid, thereby enhancing evaporation of the vaporizable working fluid and increasing thermal dissipation efficiency of the heat dissipation structure 111. In yet further embodiments, the thermal dispersion enhancement layer 232 is disposed along lateral surfaces 403 of the first dielectric layer 226 defining a bottom of the second portion 110p2 of each of the vapor chambers 110. Thus, in some embodiments, the thermal dispersion enhancement layer 232 is disposed on all of the surfaces of the support structure 112 defining the vapor chambers 110, thereby increasing an area of the thermal dispersion enhancement layer 232 and an overall heat dissipation efficiency of the semiconductor package structure.

FIG. 4C illustrates a cross-sectional view 400c of some other embodiments of the semiconductor package structure of FIG. 4B, where the dielectric layer (236 of FIG. 4B) is omitted from the thermal dispersion enhancement structure 231 and the second thermal dispersion enhancement structure 402. In some embodiments, the seed layer 234 of the thermal dispersion enhancement structure 231 directly contacts surfaces of the second substrate 230 defining the second portion 110p2 of the vapor chambers 110 and the seed layer 234 of the second thermal dispersion enhancement structure 402 directly contacts surfaces of the first substrate 224 defining the first portion 110p1 of the vapor chambers 110.

FIG. 4D illustrates a cross-sectional view 400d of some other embodiments of the semiconductor package structure of FIG. 2, where opposing sidewalls of the second substrate 230 defining the second portion 110p2 of each of the vapor chambers 110 are slanted relative to a plane extending along a bottom surface of the second substrate 230. In various embodiments, the opposing sidewalls of the second substrate 230 are each slanted such that an individual sidewall has an obtuse angle relative to the bottom surface of the second substrate 230 as shown in FIG. 4D. Accordingly, the second portion 110p2 of each of the vapor chambers 110 may, for example, have a pyramid shape, a cone shape, a flat-top pyramid shape, a flat-top cone shape, a frustum shape, or the like. By slanting opposing sidewalls of the second substrate 230 that define the second portion 110p2 of each of the vapor chambers 110 as illustrated in FIG. 4D, a volume of each of the vapor chambers 110 may be increased, thereby increasing an ability for the vapor chambers 110 to direct heat towards the capping structure 116 while maintaining an ability for the support structure 112 to provide structural support for the IC chips 104a-b. In various embodiments, the second portions 110p2 having the frustum shape facilitates directing vapor in the vapor chambers 110 in the vertical direction during operation of the semiconductor package structure.

FIG. 4E illustrates a cross-sectional view 400e of some other embodiments of the semiconductor package structure of FIG. 4D, where the thermal dispersion enhancement structure 231 extends along the slanted opposing sidewalls the second substrate 230 defining the second portion 110p2 of each of the vapor chambers 110.

FIG. 4F illustrates a top view 400f of some embodiments of a portion of the thermal dispersion enhancement structure 231 of the semiconductor package structure of FIG. 4A taken along the line B-B′ of FIG. 4A. In various embodiments, FIG. 4F illustrates a top view of a portion of the thermal dispersion enhancement layer 232, where the thermal dispersion enhancement layer 232 has a grid structure or a mesh structure when viewed from above. In some embodiments, the thermal dispersion enhancement layer 232 comprises a plurality of opposing sidewalls that define a plurality of openings 410, where the thermal dispersion enhancement layer 232 continuously wraps around each of the openings 410.

FIGS. 4G and 4H illustrate cross-sectional views 400g and 400h of some embodiments of enlarged views of a thermal dispersion enhancement structure disposed in a vapor chamber 110.

FIG. 4G illustrates an enlarged view of some embodiments of an individual vapor chamber 110 and the thermal dispersion enhancement structure 231 of the semiconductor package structure of FIG. 2. In some embodiments, outer sidewalls of the thermal dispersion enhancement structure 231 directly contact opposing sidewalls of the second substrate 230.

FIG. 4H illustrates an enlarged view of some embodiments of an individual vapor chamber 110, the thermal dispersion enhancement structure 231, and the second thermal dispersion enhancement structure 402 of the semiconductor package structure of FIG. 4B. In some embodiments, portions of the seed layer 234 and the thermal dispersion enhancement layer 232 of the second thermal dispersion enhancement structure 402 directly overlie a top surface of the first substrate 224.

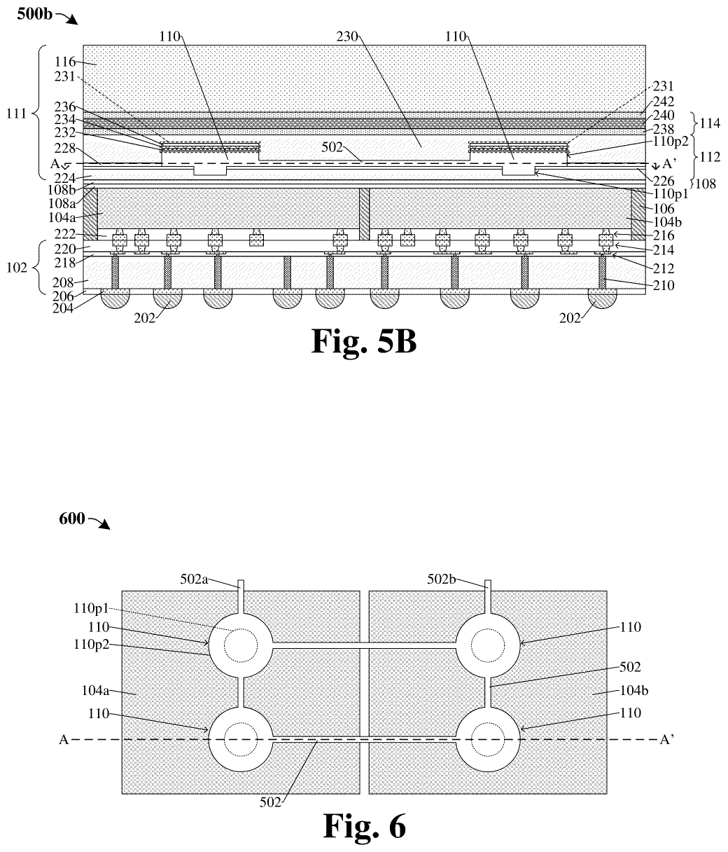

FIG. 5A illustrates a cross-sectional view 500a of some other embodiments of the semiconductor package structure of FIG. 2, where the heat dissipation structure 111 comprises at least one vapor chamber 110 having a second portion 110p2 that continuously laterally extends from over the first IC chip 104a to over the second IC chip 104b. In various embodiments, the vapor chamber 110 comprises the second portion 110p2 directly over both the first and second IC chips 104a-b and at least two first portions 110p1. In some embodiments, the at least two first portions 110p1 of the vapor chamber 110 directly overlies a corresponding region 101 of the first and second IC chips 104a-b. In such embodiment, each region 101 of the first and second IC chips 104a-b is a potential localized high temperature region of the corresponding IC chip and may comprise high-power semiconductor devices, densely packed semiconductor devices, and/or a high compute component (e.g., a CPU, a GPU, etc.) of the IC chip. In various embodiments, the first portions 110p1 overlying the corresponding region 101 of the IC chips 104a-b mitigates the formation of localized high temperature regions in the IC chips 104a-b. By virtue of the second portion 110p2 of the vapor chamber 110 overlying both the first and second IC chips 104a-b, an area of the vapor chamber 110 is increased, thereby increasing an ability to efficiently dissipate heat in the vertical direction towards the capping structure 116 and away from the IC chips 104a-b.

FIG. 5B illustrates a cross-sectional view 500b of some other embodiments of the semiconductor package structure of FIG. 2, where the semiconductor package structure further comprises one or more vapor channels 502 disposed in the support structure 112. The one or more vapor channels 502 continuously extends between adjacent vapor chambers in the plurality of vapor chambers 110. In various embodiments, the one or more vapor channels 502 are configured to fluidly connect the plurality of vapor chambers 110 to one another. In some embodiments, the one or more vapor channels 502 are formed by one or more surfaces of the second substrate 230 and/or one or more surfaces of the first substrate 224.

FIG. 6 illustrates a layout view 600 of some embodiments of the semiconductor package structure of FIG. 5B taken along the line A-A′ of FIG. 5B. For ease of illustration, the vapor chambers 110, the vapor channels 502, and the IC chips 104a-b of the semiconductor package structure of FIG. 5B are illustrated in FIG. 6 while other structures of FIG. 5B are omitted.

As illustrated in FIG. 6, the vapor channels 502 continuously laterally extend between adjacent vapor chambers 110 and are configured to fluidly connect the vapor chambers 110 to one another. In some embodiments, each vapor channel 502 continuously extends between the second portions 110p2 of adjacent vapor chambers 110. A first and second vapor channel 502a-b continuously extend from a corresponding vapor channel 502 to a point offset from the first and second IC chips 104a-b. In some embodiments, the first and second vapor channels 502a-b extend to other vapor chambers (not shown) disposed over other IC chips (not shown) in the semiconductor package structure. In further embodiments, the first and second vapor channels 502a-b are fluidly connected to one or more vertical vapor pipes (not shown) that extend in a vertical direction orthogonal to top surfaces of the first and second IC chips 104a-b when viewed in cross section (e.g., when viewed in the cross-sectional view 500b of FIG. 5B). In yet further embodiments, one or more pipe plugs (not shown) are disposed in the vertical vapor pipes and are configured to seal the vapor chambers 110 with a corresponding predefined pressure and/or seal the vapor chambers 110 with the working fluid or a working vapor. Further, the one or more vertical vapor pipes are configured to facilitate charging the plurality of vapor chambers with a working fluid or a working vapor. For example, the working fluid or working vapor may be flowed into the plurality of vapor chambers 110 by way of the vertical vapor pipes, and after flowing the working fluid or working vapor into the plurality of vapor chambers 110 the pipe plugs may be placed in the vertical vapor pipes to seal the vapor chambers 110. In various embodiments, the vapor channels 502 facilitate the vapor chambers 110 having a same predefined pressure and/or each having a substantial similar concentration or amount of the working fluid or the working vapor. As a result, the vapor chambers 110 may uniformly transfer heat in the vertical direction towards the capping structure (116 of FIG. 5B) across the semiconductor package structure. This enhances thermal dissipation across the semiconductor package structure, thereby increasing an overall performance and reliability of the semiconductor package structure is increased.

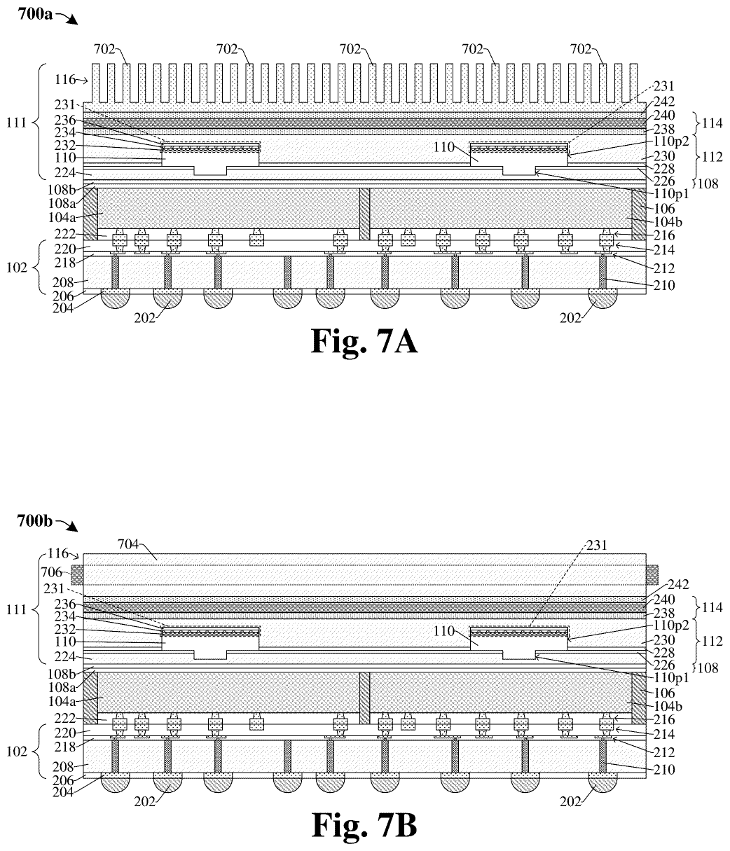

FIG. 7A illustrates a cross-sectional view 700a of some other embodiments of the semiconductor package structure of FIG. 2, where the capping structure 116 is or comprises a heat sink structure including a plurality of heat sink fins 702 vertically extending upward from a base of the heat sink structure. The heat sink fins 702 are laterally spaced from one another such that air may travel between the heat sink fins 702 and dissipate heat collected at the capping structure 116 into the external environment. In various embodiments, a fan (not shown) may be configured to direct air between the heat sink fins 702 to carry heat away from the capping structure 116, thereby reducing a temperature of the capping structure 116. As a result, an ability for the heat dissipation structure 111 to efficiently transfer heat away from the plurality of IC chips 104a-b is increased, thereby further increasing a performance of the semiconductor package structure.

FIG. 7B illustrates a cross-sectional view 700b of some other embodiments of the semiconductor package structure of FIG. 2, where the capping structure 116 is or comprises a liquid cooling structure including a liquid cooling housing structure 704 and a liquid channel structure 706. The liquid channel structure 706 is disposed in the liquid cooling housing structure 704. In some embodiments, during operation of the semiconductor package structure a liquid pump (not shown) is configured to circulate a liquid (e.g., water or another coolant) across the liquid channel structure 706. The liquid absorbs heat generated from the plurality of IC chips 104a-b and is configured to be transported away to an external cooler or heat exchanger (not shown) and/or is configured to be cooled by another structure (e.g., by a heat sink structure disposed on the capping structure 116 (not shown)). This facilitates further increasing a heat dissipation performance of the semiconductor package structure, thereby further increasing a performance of the semiconductor package structure.

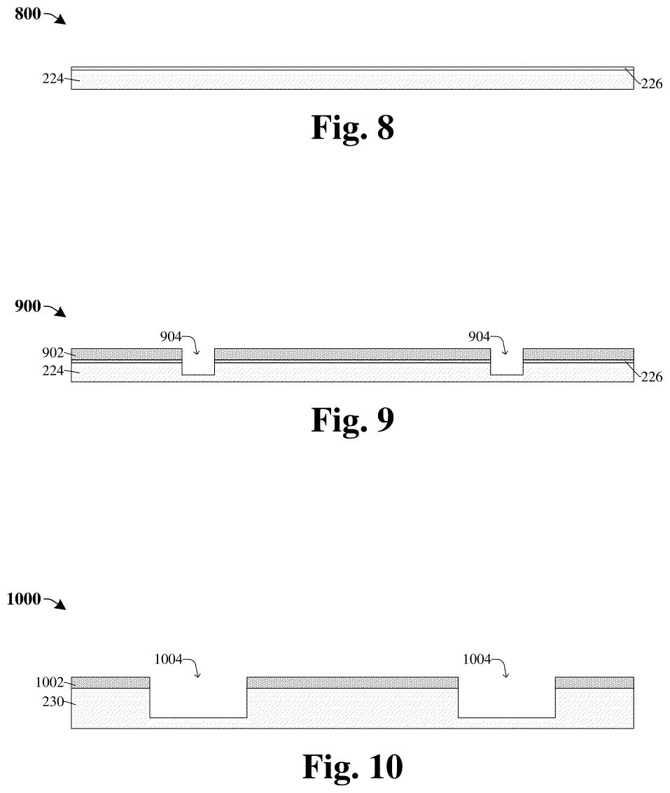

FIGS. 8-17 illustrate cross-sectional views 800-1700 of some embodiments of a method of forming a semiconductor package structure comprising a heat dissipation structure that includes one or more vapor chambers over a plurality of integrated circuit (IC) chips. Although the cross-sectional views 800-1700 shown in FIGS. 8-17 are described with reference to a method, it will be appreciated that the structures shown in FIGS. 8-17 are not limited to the method but rather may stand alone separate of the method. Furthermore, although FIGS. 8-17 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

A shown in cross-sectional view 800 of FIG. 8, a first dielectric layer 226 is formed on a first substrate 224. In some embodiments, the first dielectric layer 226 may be formed on the first substrate 224 by a chemical vapor deposition (CVD) process, a physical vapor deposition (PVD) process, an atomic layer deposition (ALD) process, a thermal oxidation process, or some other suitable deposition or growth process. The first substrate 224 may, for example, be or comprise silicon, epitaxial silicon, germanium, silicon germanium, or some other suitable substrate material. The first dielectric layer 226 may, for example, be or comprise an oxide such as silicon dioxide or some other suitable material.

As shown in cross-sectional view 900 of FIG. 9, a patterning process is performed on the first dielectric layer 226 and the first substrate 224 to form a plurality of first openings 904 in the first substrate 224. In some embodiments, the patterning process includes: forming a masking layer 902 on the first substrate 224; performing an etching process (e.g., a dry etch process) on the first substrate 224 and the first dielectric layer 226 according to the masking layer 902; and removing the masking layer 902 from over the first substrate 224 (not shown). In other embodiments, a process for forming the first openings 904 includes: patterning the first substrate 224 to form the first openings 904 in the first substrate 224; depositing (e.g., by CVD, PVD, ALD, thermal oxidation, etc.) the first dielectric layer 226 on the first substrate 224; and performing an etch process (e.g., a dry etch process, a wet etch process, etc.) to remove portions of the first dielectric layer 226 from over a lower surface of the first substrate 224 that defines bottoms of the first openings 904. In various embodiments, a thermal dispersion enhancement structure (e.g., 402 of FIGS. 4B and 4C) is formed along one or more surfaces of the first substrate 224 that defines the first openings 904.

As shown in cross-sectional view 1000 of FIG. 10, a patterning process is performed on a second substrate 230 to form a plurality of second openings 1004 in the second substrate 230. In some embodiments, the patterning process includes: forming a masking layer 1002 on the second substrate 230; performing an etching process (e.g., a dry etch process) on the second substrate 230; and removing the masking layer 1002 from over the second substrate 230 (not shown). The second substrate 230 may, for example, be or comprise silicon, epitaxial silicon, germanium, silicon germanium, or some other suitable substrate material

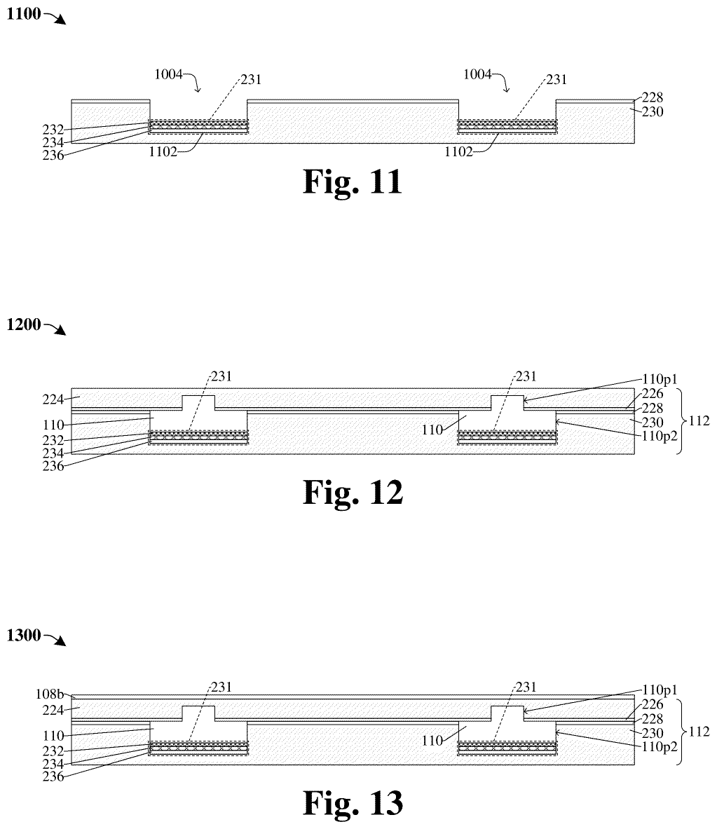

As shown in cross-sectional view 1100 of FIG. 11, a second dielectric layer 228 is formed on the second substrate 230 and a thermal dispersion enhancement structure 231 is formed on lateral surfaces 1102 of the second substrate 230 that define at least a portion of each of the second openings 1004. In some embodiments, the second dielectric layer 228 may be formed on the second substrate 230 by a CVD process, a PVD process, an ALD process, a thermal oxidation process, or some other suitable deposition or growth process. In various embodiments, the thermal dispersion enhancement structure 231 includes a dielectric layer 236, a seed layer 234 on the dielectric layer 236, and a thermal dispersion enhancement layer 232 on the seed layer 234. The dielectric layer 236 may be formed on the lateral surfaces 1102 of the second substrate 230 by, for example, a CVD process, a PVD process, an ALD process, a thermal oxidation process, or some other suitable deposition or growth process. The seed layer 234 may be formed on the dielectric layer 236 by, for example, a CVD process, a PVD process, or some other suitable growth or deposition process. The thermal dispersion enhancement layer 232 may by formed on the seed layer 234 by, for example, a CVD process, a PVD process, an electroplating process, an electroless plating process, or some other suitable growth or deposition process. In various embodiments, the thermal dispersion enhancement layer 232 has a grid structure or a mesh structure when viewed in top view (e.g., as illustrated and/or described in FIG. 4F).

In yet further embodiments, the second dielectric layer 228 may be formed on the second substrate 230 before the patterning process of FIG. 10. In such embodiments, the second dielectric layer 228 is etched during the patterning process of FIG. 10. The second dielectric layer 228 may, for example, be or comprise silicon dioxide or some other suitable dielectric material. The seed layer 234 may, for example, be or comprise titanium, tantalum, a nitride (e.g., titanium nitride, tantalum nitride, etc.), copper, or the like. The thermal dispersion enhancement layer 232 may, for example, be or comprise copper or some other suitable material.

As shown in cross-sectional view 1200 of FIG. 12, a vapor chamber bonding process is performed to bond the first substrate 224 to the second substrate 230 and form or define a plurality of vapor chambers 110, thereby forming or defining a support structure 112. In some embodiments, the vapor chambers 110 are defined by one or more surfaces of the support structure 112. The vapor chambers 110 each comprise a first portion 110p1 and a second portion 110p2. In some embodiments, a width of the first portion 110p1 is less than a width of the second portion 110p2. In various embodiments, the vapor chamber bonding process includes performing a vapor chamber charging process to form or deposit a vaporizable working fluid or working vapor in the first and/or second openings (904 of FIGS. 9 and/or 1004 of FIG. 11) and a bonding process to bond the first substrate 224 to the second substrate 230 and seal the vapor chambers 110. By performing the vapor chamber charging process before the bonding process, the plurality of vapor chambers 110 may be sealed with the vaporizable working fluid or working vapor. In various embodiments, a process for forming the plurality of vapor chambers 110 includes the processing steps illustrated and/or described in FIGS. 8-12.

In some embodiments, the vapor chamber charging process includes disposing the vaporizable working fluid in the first and/or second openings (904 of FIGS. 9 and/or 1004 of FIG. 11) by an injection filling process, a vacuum filling process, some other suitable process, or any combination of the foregoing. In various embodiments, the vaporizable working fluid may, for example, be or comprise a chlorofluorocarbon, a hydrochlorofluorocarbon, water, alcohol, silicon oil, liquid nitrogen, fluorine-containing fluid, acetone, methanol, ethanol, heptane, ammonia, some other suitable cooling liquid, or any combination of the foregoing. In some embodiments, the bonding process includes performing a fusion bonding process or some other suitable bonding process. In various embodiments, the first openings (e.g., 904 of FIG. 9) formed in the first substrate 224 (e.g., as illustrated and/or described in FIG. 9) correspond to the first portions 110p1 of the vapor chambers 110 and the second openings (e.g., 1004 of FIG. 11) formed in the second substrate 230 (e.g., as illustrated and/or described in FIG. 10) correspond to the second portions 110p2 of the vapor chambers 110.

As shown in cross-sectional view 1300 of FIG. 13, a second dielectric bond layer 108b is formed on the support structure 112. In some embodiments, the second dielectric bond layer 108b is formed on the first substrate 224 of the support structure 112 by a CVD process, a PVD process, an ALD process, a thermal oxidation process, or some other suitable deposition or growth process. In various embodiments, before forming the second dielectric bond layer 108b a planarization process (e.g., a chemical mechanical polishing (CMP)) is performed on the first substrate 224 such that an upper surface of the first substrate 224 that the second dielectric bond layer 108b is formed on is substantially flat.

As shown in cross-sectional view 1400 of FIG. 14, an IC structure 1402 is provided or otherwise formed and the support structure 112 is bonded to the IC structure 1402. The IC structure 1402 includes a plurality of IC chips 104a-b over a base structure 102. The plurality of IC chips 104a-b may be configured as illustrated and/or described in FIG. 2. In various embodiments, the base structure 102 is configured as an interposer that comprises a lower substrate 208, a plurality of TSVs 210, a plurality of conductive interconnect structures 212, and a first plurality of conductive bond structures 214. In some embodiments, forming the IC structure 1402 includes: forming or otherwise providing the base structure 102 and the plurality of IC chips 104a-b; bonding the plurality of IC chips 104a-b to the base structure 102; and forming a filler layer 106 over the base structure 102 and around the IC chips 104a-b. In various embodiments, bonding the support structure 112 to the IC structure 1402 includes: forming (e.g., by CVD, PVD, ALD, etc.) a first dielectric bond layer 108a on the plurality of IC chips 104a-b and the filler layer 106; performing an alignment process (e.g., an optical alignment processes utilizing one or more alignment marks) to accurately align the support structure 112 over the plurality of IC chips 104a-b; and performing a bonding process (e.g., a fusion bonding process) to bond the support structure 112 to the IC structure 1402. In further embodiments, before forming the first dielectric bond layer 108a on the plurality of IC chips 104a-b a planarization process (e.g., a CMP process) is performed on the plurality of IC chips 104a-b and the filler layer 106 such that upper surfaces of the IC chips 104a-b and the filler layer 106 are substantially flat and/or coplanar with one another.

In yet further embodiments, a first plurality of conductive structures (not shown) may be formed or disposed in the first dielectric bond layer 108a and a second plurality of conductive structures (not shown) may be formed or disposed in the second dielectric bond layer 108b before bonding the support structure 112 to the IC structure 1402. The conductive structures may, for example, be or comprise copper or some other suitable material. In various embodiments, the first plurality of conductive structures are aligned with the second plurality of conductive structures while bonding the support structure to the IC structure 1402. In such embodiments, the support structure 112 meets the IC structure 1402 at a bonding interface that includes dielectric-to-dielectric bonds and conductor-to-conductor bonds. In various embodiments, one or more of the conductive structures is/are laterally aligned with each of the vapor chambers 110.

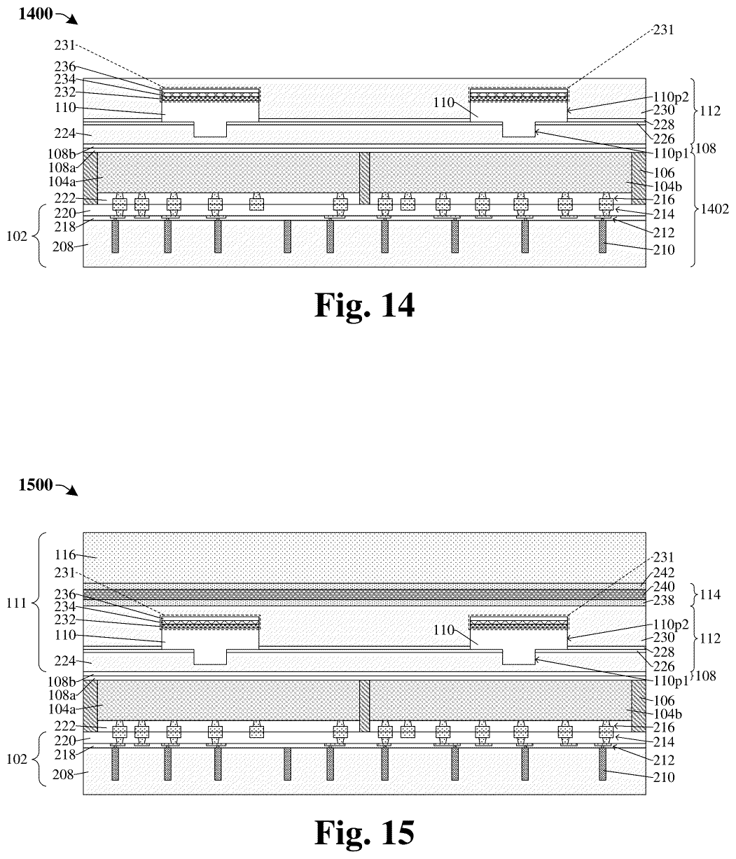

As shown in cross-sectional view 1500 of FIG. 15, a thermal interface structure 114 and a capping structure 116 are formed over the support structure 112, thereby defining or forming a heat dissipation structure 111 over the plurality of IC chips 104a-b. In some embodiments, the thermal interface structure 114 includes a first thermal spreading layer 238, a thermal interface layer 240, and a second thermal spreading layer 242. The first and second thermal spreading layers 238, 242 may, for example, be or comprise a metal, such as copper, aluminum, nickel, cobalt, some other metal, or an alloy thereof. The thermal interface layer 240 may, for example, be or comprise lead, tin, silver, copper, indium, an alloy (e.g., a solder alloy) thereof, or some other suitable material. The capping structure 116 may, for example, be or comprise copper, aluminum, some other suitable high thermal conductive material, or the like.

In various embodiments, a process for forming the thermal interface structure 114 and the capping structure 116 includes: forming (e.g., by CVD, PVD, electroplating, electroless plating, etc.) the first thermal spreading layer 238 on the second substrate 230; forming (e.g., by CVD, PVD, electroplating, electroless plating, etc.) the second thermal spreading layer 242 on the capping structure 116; forming (e.g., by a screen-printing process, a spraying process, a paste or grease application process, a dispensing process, a deposition process, etc.) the thermal interface layer 240 on the first thermal spreading layer 238; and performing a bonding process (e.g., a reflow process) to bond the second thermal spreading layer 242 and the capping structure 116 to the support structure 112 by way of the thermal interface layer 240. For example, the bonding process includes heating the thermal interface layer 240 to its melting point after disposing the capping structure 116 on the thermal interface layer 240 and performing a cooling process to bond the capping structure 116 to the support structure 112.

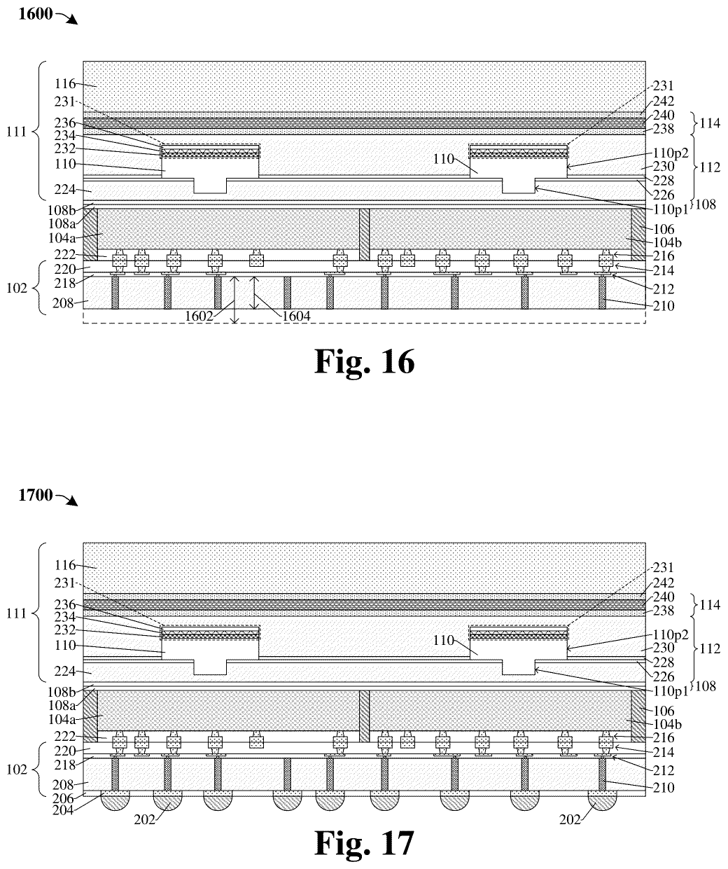

As shown in cross-sectional view 1600 of FIG. 16, a thinning process is performed on the lower substrate 208. In some embodiments, the thinning process reduces a thickness of the lower substrate 208 from a first thickness 1602 to a second thickness 1604 and exposes bottom surfaces of the TSVs 210. The thinning process may, for example, be or include a CMP process, a mechanical grinding process, or some other suitable process.

As shown in cross-sectional view 1700 of FIG. 17, a plurality of lower bond pads 204 and a plurality of solder bumps 202 are formed along a lower surface of the lower substrate 208. In some embodiments, forming the plurality of lower bonding pads 204 includes: forming (e.g., by CVD, PVD, ALD, etc.) a lower dielectric layer 206 along the lower surface of the lower substrate 208; etching the lower dielectric layer 206 to form a plurality of openings in the lower dielectric layer 206; and forming the plurality of lower bonding pads 204 in the plurality of openings.

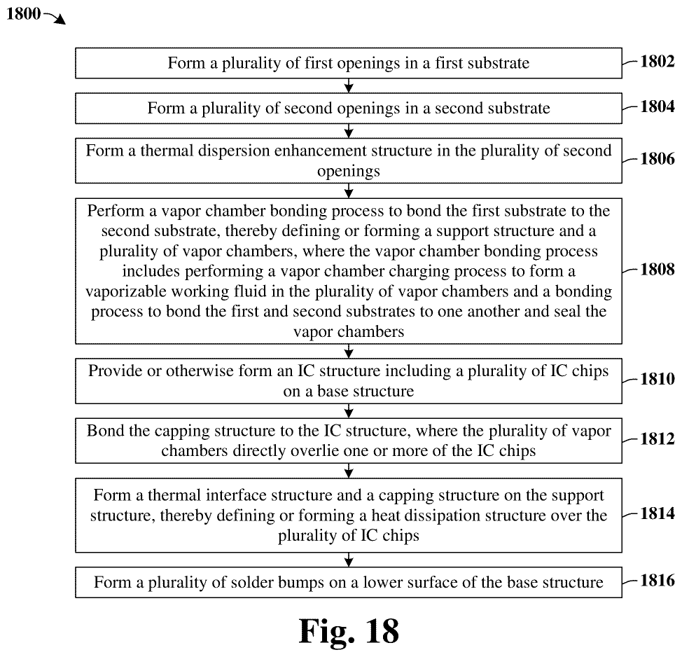

FIG. 18 illustrates a flow diagram of some embodiments of a method 1800 of forming a semiconductor package structure comprising a heat dissipation structure that includes one or more vapor chambers over a plurality of IC chips. Although the method 1800 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 1802, a plurality of first openings are formed in a first substrate. FIG. 9 illustrates a cross-sectional view 900 corresponding to some embodiments of act 1802.

At act 1804, a plurality of second openings are formed in a second substrate. FIG. 10 illustrates a cross-sectional view 1000 corresponding to some embodiments of act 1804.

At act 1806, a thermal dispersion enhancement structure is formed in the plurality of second openings. FIG. 11 illustrates a cross-sectional view 1100 corresponding to some embodiments of act 1806.

At act 1808, a vapor chamber bonding process is performed to bond the first substrate to the second substrate, thereby defining or forming a support structure and a plurality of vapor chambers. The vapor chamber bonding process includes performing a vapor chamber charging process to form a vaporizable working fluid in the plurality of vapor chambers and a bonding process to bond the first and second substrates to one another and seal the vapor chambers. FIG. 12 illustrates a cross-sectional view 1200 corresponding to some embodiments of act 1808.

At act 1810, an IC structure including a plurality of IC chips on a base structure is provided or otherwise formed. FIG. 14 illustrates a cross-sectional view 1400 corresponding to some embodiments of act 1810.

At act 1812, the capping structure is bonded to the IC structure, where the plurality of vapor chambers directly overlie one or more of the IC chips. FIG. 14 illustrates the cross-sectional view 1400 corresponding to some embodiments of act 1812.

At act 1814, a thermal interface structure and a capping structure are formed on the support structure, thereby defining or forming a heat dissipation structure over the plurality of IC chips. FIG. 15 illustrates a cross-sectional view 1500 corresponding to some embodiments of act 1814.

At act 1816, a plurality of solder bumps are formed on a lower surface of the baes structure. FIG. 17 illustrates a cross-sectional view 1700 corresponding to some embodiments of act 1816.

Accordingly, in some embodiments, the present disclosure relates to a semiconductor package structure having a heat dissipation structure including one or more vapor chambers over a plurality of IC chips and a capping structure over the one or more vapor chambers.

In some embodiments, the present application provides a semiconductor package structure. The semiconductor package structure includes: a support structure comprising a first surface opposite a second surface; a first integrated circuit (IC) chip on the first surface of the support structure; a capping structure on the second surface of the support structure; and a vapor chamber disposed in the support structure and over at least a portion of the first IC chip. In an embodiment, the vapor chamber comprises a first chamber portion and a second chamber portion overlying the first chamber portion, wherein a width of the first chamber portion is less than a width of the second chamber portion. In an embodiment, the width of the first chamber portion is constant, wherein the width of the second chamber portion continuously decreases from a bottom of the second chamber portion in a direction towards the capping structure. In an embodiment, the support structure comprises a first substrate and a second substrate over the first substrate, wherein the first chamber portion is defined by one or more surfaces of the first substrate and the second chamber portion is defined by one or more surfaces of the second substrate. In an embodiment, the vapor chamber comprises a vaporizable working fluid sealed within the vapor chamber. In an embodiment, the support structure comprises one or more substrates and one or more dielectric layers, wherein the capping structure has a thermal conductivity greater than that of the one or more substrates and the one or more dielectric layers. In an embodiment, a height of the capping structure is less than a height of the support structure. In an embodiment, the semiconductor package structure further includes a thermal interface structure disposed between the capping structure and the support structure, wherein the thermal interface structure comprises a first thermal spreading layer, a second thermal spreading layer, and a thermal interface layer between the first and second thermal spreading layers, wherein the first and second thermal spreading layers comprise a first material different from a second material of the thermal interface layer.

In some embodiments, the present application provides a semiconductor package structure. The semiconductor package structure includes an interposer structure comprising a plurality of conductive interconnect structures; a plurality of integrated circuit (IC) chips on and electrically coupled to the plurality of conductive interconnect structures; and a heat dissipation structure on the plurality of IC chips, wherein the heat dissipation structure includes: a support structure on the plurality of IC chips; a thermal interface structure on the support structure; a heat spreader structure on the thermal interface structure; and one or more vapor chambers embedded in the support structure, wherein the one or more vapor chambers respectively comprise a bottom surface with a first width facing the plurality of IC chips and a top surface with a second width facing the heat spreader structure, wherein the first width is less than the second width. In an embodiment, a thermal dispersion enhancement structure is disposed in the one or more vapor chambers, wherein the thermal dispersion enhancement structure comprises a thermal dispersion enhancement layer having a thermal conductivity greater than that of the support structure. In an embodiment, the thermal dispersion enhancement layer has a mesh layout when viewed in top view. In an embodiment, the one or more vapor chambers comprise a vaporizable working fluid sealed therein, and wherein the thermal dispersion enhancement layer is configured to assist in evaporating the vaporizable working fluid. In an embodiment, the thermal dispersion enhancement layer and the heat spreader structure respectively comprise a same conductive material. In an embodiment, a height of the heat spreader structure is greater than a height of the one or more vapor chambers. In an embodiment, a ratio of a height of the heat spreader structure and a height of the support structure is within a range of 0.34 to 1.

In some embodiments, the present application provides a method for forming a semiconductor package structure, the method includes: disposing a plurality of integrated circuit (IC) chips on an interposer structure; forming a vapor chamber within a support structure; bonding the support structure to the plurality of IC chips, wherein the vapor chamber overlies at least a portion of an individual IC chip in the plurality of IC chips; and bonding a capping structure to the support structure, wherein a thermal conductivity of the capping structure is greater than a thermal conductivity of the support structure. In an embodiment, forming the vapor chamber includes etching a first substrate to define a first chamber portion in the first substrate; etching a second substrate to define a second chamber portion in the second substrate, wherein a width of the second chamber portion is greater than a width of the first chamber portion; and performing a bonding process to bond the first substrate to the second substrate, thereby sealing the vapor chamber, wherein the first chamber portion is laterally aligned with the second chamber portion. In an embodiment, forming the vapor chamber further includes disposing at least one vaporizable working fluid in the first chamber portion and/or the second chamber portion before performing the bonding process, wherein the bonding process seals the at least one vaporizable working fluid in the vapor chamber. In an embodiment, the method further includes forming a thermal dispersion enhancement structure along at least one surface of the one or more surfaces of the support structure defining the vapor chamber, wherein the thermal dispersion enhancement structure comprises a wicking layer. In an embodiment, the support structure comprises a substrate, wherein the substrate comprises silicon and the capping structure comprises copper.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a support structure comprising a first surface opposite a second surface;
a first integrated circuit (IC) chip on the first surface of the support structure;
a capping structure on the second surface of the support structure; and
a vapor chamber disposed in the support structure and over at least a portion of the first IC chip.

2. The semiconductor package structure of claim 1, wherein the vapor chamber comprises a first chamber portion and a second chamber portion overlying the first chamber portion, wherein a width of the first chamber portion is less than a width of the second chamber portion.

3. The semiconductor package structure of claim 2, wherein the width of the first chamber portion is constant, wherein the width of the second chamber portion continuously decreases from a bottom of the second chamber portion in a direction towards the capping structure.

4. The semiconductor package structure of claim 2, wherein the support structure comprises a first substrate and a second substrate over the first substrate, wherein the first chamber portion is defined by one or more surfaces of the first substrate and the second chamber portion is defined by one or more surfaces of the second substrate.

5. The semiconductor package structure of claim 1, wherein the vapor chamber comprises a vaporizable working fluid sealed within the vapor chamber.

6. The semiconductor package structure of claim 1, wherein the support structure comprises one or more substrates and one or more dielectric layers, wherein the capping structure has a thermal conductivity greater than that of the one or more substrates and the one or more dielectric layers.

7. The semiconductor package structure of claim 6, wherein a height of the capping structure is less than a height of the support structure.

8. The semiconductor package structure of claim 1, further comprising:
a thermal interface structure disposed between the capping structure and the support structure, wherein the thermal interface structure comprises a first thermal spreading layer, a second thermal spreading layer, and a thermal interface layer between the first and second thermal spreading layers, wherein the first and second thermal spreading layers comprise a first material different from a second material of the thermal interface layer.

9. A semiconductor package structure, comprising:
an interposer structure comprising a plurality of conductive interconnect structures;
a plurality of integrated circuit (IC) chips on and electrically coupled to the plurality of conductive interconnect structures; and
a heat dissipation structure on the plurality of IC chips, wherein the heat dissipation structure comprises:
a support structure on the plurality of IC chips;
a thermal interface structure on the support structure;
a heat spreader structure on the thermal interface structure; and
one or more vapor chambers embedded in the support structure, wherein the one or more vapor chambers respectively comprise a bottom surface with a first width facing the plurality of IC chips and a top surface with a second width facing the heat spreader structure, wherein the first width is less than the second width.

10. The semiconductor package structure of claim 9, further comprising:
a thermal dispersion enhancement structure disposed in the one or more vapor chambers, wherein the thermal dispersion enhancement structure comprises a thermal dispersion enhancement layer having a thermal conductivity greater than that of the support structure.

11. The semiconductor package structure of claim 10, wherein the thermal dispersion enhancement layer has a mesh layout when viewed in top view.

12. The semiconductor package structure of claim 10, wherein the one or more vapor chambers comprise a vaporizable working fluid sealed therein, and wherein the thermal dispersion enhancement layer is configured to assist in evaporating the vaporizable working fluid.

13. The semiconductor package structure of claim 10, wherein the thermal dispersion enhancement layer and the heat spreader structure respectively comprise a same conductive material.

14. The semiconductor package structure of claim 9, wherein a height of the heat spreader structure is greater than a height of the one or more vapor chambers.

15. The semiconductor package structure of claim 9, wherein a ratio of a height of the heat spreader structure and a height of the support structure is within a range of 0.34 to 1.

16. A method of forming a semiconductor package structure, comprising:
disposing a plurality of integrated circuit (IC) chips on an interposer structure;
forming a vapor chamber within a support structure;
bonding the support structure to the plurality of IC chips, wherein the vapor chamber overlies at least a portion of an individual IC chip in the plurality of IC chips; and
bonding a capping structure to the support structure, wherein a thermal conductivity of the capping structure is greater than a thermal conductivity of the support structure.

17. The method of claim 16, wherein forming the vapor chamber comprises:
etching a first substrate to define a first chamber portion in the first substrate;
etching a second substrate to define a second chamber portion in the second substrate, wherein a width of the second chamber portion is greater than a width of the first chamber portion; and
performing a bonding process to bond the first substrate to the second substrate, thereby sealing the vapor chamber, wherein the first chamber portion is laterally aligned with the second chamber portion.

18. The method of claim 17, wherein forming the vapor chamber further comprises:
disposing at least one vaporizable working fluid in the first chamber portion and/or the second chamber portion before performing the bonding process, wherein the bonding process seals the at least one vaporizable working fluid in the vapor chamber.

19. The method of claim 16, further comprising:
forming a thermal dispersion enhancement structure along at least one surface of the one or more surfaces of the support structure defining the vapor chamber, wherein the thermal dispersion enhancement structure comprises a wicking layer.

20. The method of claim 16, wherein the support structure comprises a substrate, wherein the substrate comprises silicon and the capping structure comprises copper.
